(19) United States
(12) Patent Application Publication
(10) Pub. No.: US 2015/0092357 A1
(43) Pub. Date: Apr. 2, 2015

(54) PRINTED WIRING BOARD, METHOD FOR MANUFACTURING PRINTED WIRING BOARD AND PACKAGE-ON-PACKAGE

(71) Applicant: IBIDEN CO., LTD., Ogaki-shi (JP)

(72) Inventors: Kazuhiro YOSHIKAWA, Ogaki-shi (JP); Takashi KARIYA, Ogaki-shi (JP)

(73) Assignee: IBIDEN CO., LTD., Ogaki-shi (JP)

(21) Appl. No.: 14/504,969

(22) Filed: Oct. 2, 2014

(30) Foreign Application Priority Data
Oct. 2, 2013 (JP) 2013-207370

(51) Int. Cl. H05K 1/03; H05K 3/00; H05K 3/46; H05K 3/18; H05K 1/11; H05K 1/18

(52) U.S. Cl. CPC H05K 1/0306; H05K 1/113; H05K 1/181; H05K 3/465; H05K 3/188; H05K 3/0017; H05K 2201/0367; H05K 2201/10257; H05K 2203/0562; H05K 2203/0723; H05K 2203/11
USPC 361/746; 174/258; 216/13; 228/176

(57) ABSTRACT

A method for manufacturing a printed wiring board includes forming a resin insulation layer on an interlayer resin insulation layer and conductive circuits such that the resin insulation layer has first openings exposing pad portions in central portion of the interlayer layer and second openings exposing pad portions in peripheral portion of the interlayer layer, forming a seed layer on the resin insulation layer, in the first and second openings and on the pad portions, forming on the seed layer a plating resist such that the resist has resist openings exposing the second openings and having diameters greater than the second openings, filling the resist openings with electrolytic plating material via the seed layer such that metal posts are formed in the resist openings, removing the resist from the resin insulation layer, and removing the seed layer exposed on the resin insulation layer by the removing of the resist.

### CROSS-REFERENCE TO RELATED APPLICATIONS

The present application is based upon and claims the benefit of priority to Japanese Patent Application No. 2013-207370, filed Oct. 2, 2013, the entire contents of which are incorporated herein by reference.

### BACKGROUND OF THE INVENTION

1. Field of the Invention

The present invention relates to a printed wiring board having metal posts for mounting another printed wiring board (upper substrate) and to a method for manufacturing such a printed wiring board.

2. Description of Background Art

JP2003-8228A describes a method for forming a metal post on a pad of a printed wiring board. The entire contents of this publication are incorporated herein by reference.

### SUMMARY OF THE INVENTION

According to one aspect of the present invention, a method for manufacturing a printed wiring board includes forming a resin insulation layer on an interlayer resin insulation layer and conductive circuits such that the resin insulation layer has first opening portions exposing pad portions in a central portion of the interlayer resin insulation layer and second opening portions exposing pad portions in a peripheral portion of the interlayer resin insulation layer, forming a seed layer on the resin insulation layer such that the seed layer is formed on the resin insulation layer, in the first and second opening portions and on the pad portions exposed through the first and second opening portions, forming on the seed layer a plating resist such that the plating resist has resist opening portions exposing the second opening portions and having diameters greater than the second opening portions, respectively, filling the resist opening portions with electrolytic plating material via the seed layer such that metal posts are formed in the resist opening portions, respectively, removing the plating resist from the resin insulation layer, and removing the seed layer exposed on the resin insulation layer by the removing of the plating resist.

According to another aspect of the present invention, a printed wiring board includes an interlayer resin insulation layer, pad portions formed on the interlayer resin insulation layer, a resin insulation layer formed on the interlayer resin insulation layer and the pad portions such that the resin insulation layer has first opening portions exposing the pad portions in a central portion of the interlayer resin insulation layer and second opening portions exposing the pad portions in a peripheral portion of the interlayer resin insulation layer, and metal posts formed on the pad portions in the peripheral portion of the interlayer resin insulation layer, respectively, and having curved side-wall portions forming narrowed portions between the end portions and opposite end portions of the metal posts, respectively.

According to yet another aspect of the present invention, a package-on-package device includes a first substrate, an IC chip mounted on the first substrate, a second substrate mounted on the first substrate, and a mold resin layer filling the space formed between the first substrate and the IC chip. The first substrate includes an interlayer resin insulation layer, pad portions formed on the interlayer resin insulation layer, a resin insulation layer formed on the interlayer resin insulation layer and the pad portions such that the resin insulation layer has first opening portions exposing the pad portions in a central portion of the interlayer resin insulation layer and second opening portions exposing the pad portions in a peripheral portion of the interlayer resin insulation layer, and metal posts formed on the pad portions in the peripheral portion of the interlayer resin insulation layer, respectively, and having curved side-wall portions forming narrowed portions between the end portions and opposite end portions of the metal posts, respectively, the mold resin layer has opening portions exposing the end portions of the metal posts, respectively, the first substrate has first bumps mounting the IC chip on the pad portions in the central portion of the interlayer resin insulation layer, and the second substrate has second bumps connecting to the end portions of the metal posts exposed from the opening portions of the mold resin layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 shows a cross-sectional view of an applied example of a printed wiring board according to a first embodiment of the present invention;

FIG. 2 shows a cross-sectional view of a printed wiring board according to the first embodiment;

FIG. 3(A) is a plan view of a mounting surface, and 3(B) is a view showing a mounting surface with metal posts;

FIG. 4(A)-4(B) show steps for manufacturing metal posts of a printed wiring board according to the first embodiment;

FIG. 5(A)-5(B) show steps for manufacturing metal posts of a printed wiring board according to the first embodiment;

FIG. 6(A)-6(B) show steps for manufacturing metal posts of a printed wiring board according to the first embodiment;

FIG. 7(A)-7(B) show steps for manufacturing metal posts of a printed wiring board according to the first embodiment;

FIG. 8(A)-8(B) show steps for manufacturing metal posts of a printed wiring board according to the first embodiment;

FIG. 9(A)-9(B) show steps for manufacturing metal posts of a printed wiring board according to the first embodiment;

FIG. 10 is a cross-sectional view of an applied example of a printed wiring board according to a second embodiment of the present invention;

FIG. 11(A)-11(B) show steps for manufacturing metal posts of a printed wiring board according to the second embodiment; and

FIG. 12(A)-12(B) show steps for manufacturing metal posts of a printed wiring board according to the second embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

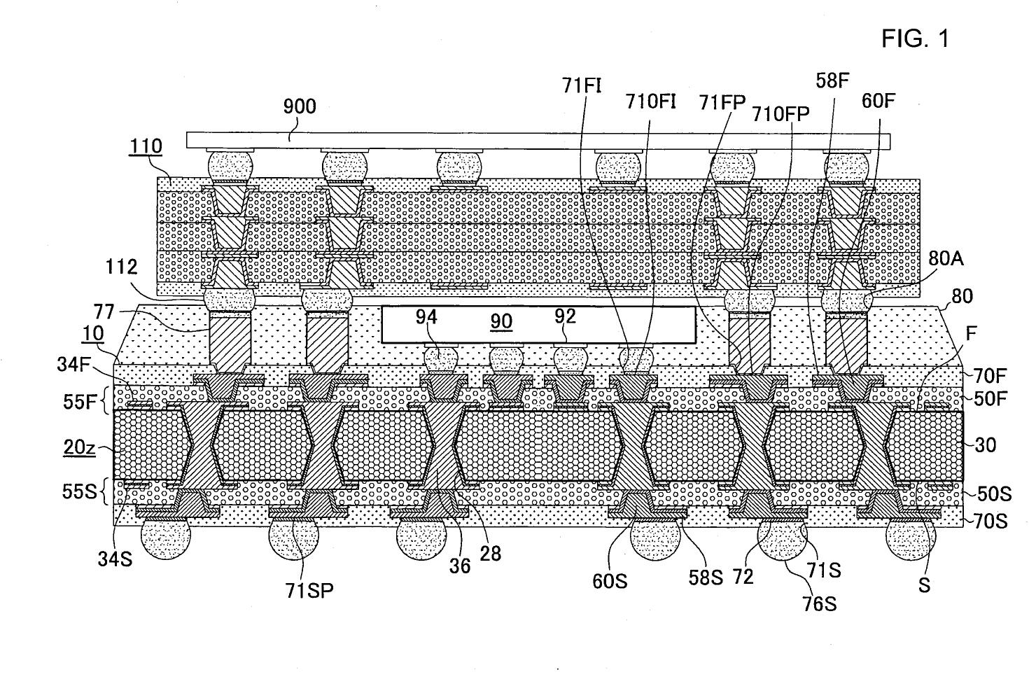

FIG. 1 shows an applied example of printed wiring board 10 according to a first embodiment of the present invention.

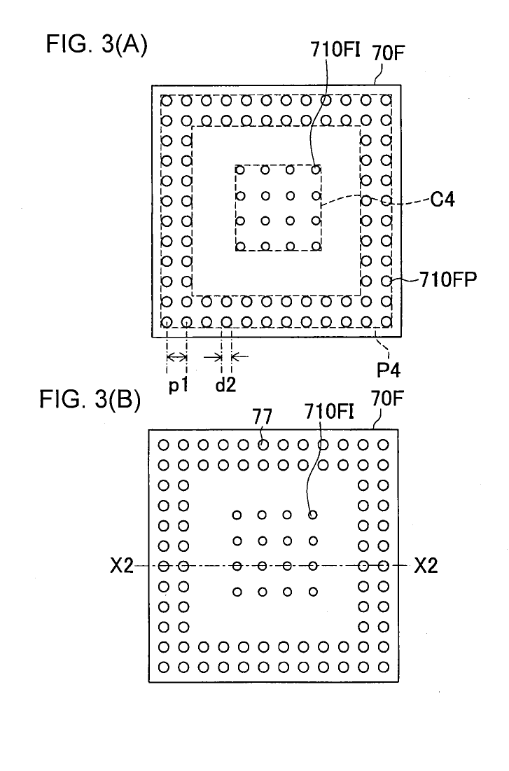

Printed wiring board 10 has pads (first pads) (710FI) for mounting electronic component 90 such as an IC chip, and pads (second pads) (710FP) for mounting another printed wiring board (upper substrate) 110. Electronic component 900 such as a memory is mounted on the other printed wiring board. Pad group (C4) is formed with multiple pads (710FI) (see FIG. 3(A)), and pad group (C4) is formed in an approximate center of printed wiring board 10. Pads (710FP) are formed in peripheral region (P4) surrounding pad group (C4) (see FIG. 3(A)). On pads (710FP), bonding posts (metal posts) 77 for mounting an upper substrate are formed. The shape of metal posts is a circular column, for example. Metal posts 77 work to electrically connect printed wiring board 10 and printed wiring board 110. In addition, even if pitch (p1) of pads (710FP) is 0.3 mm or less, the distance between printed wiring board 10 of the present embodiment and printed wiring board (upper substrate) 110 is secured by metal posts 77. Because of metal posts 77, a constant distance is maintained between printed wiring board 10 of the embodiment and printed wiring board (upper substrate) 110 even when pitch (p1) of pads (710FP) is 0.25 mm or less. Insulation is maintained between adjacent pads. Pitch (p1) is the distance between the centers of adjacent pads (710FP).

The printed wiring board of the present embodiment may have a core substrate, or it may be a coreless printed wiring board. A printed wiring board with a core substrate and its manufacturing method are described in JP2007-227512A, for example. The entire contents of JP2007-227512A are incorporated herein by reference. A coreless substrate and its manufacturing method are described in JP2005-236244A, for example.

Such a coreless substrate is formed by alternately laminating an interlayer resin insulation layer and a conductive layer, and all the interlayer resin insulation layers each have a thickness of 60 μm or less, for example.

Printed wiring board 10 of the first embodiment has core substrate 30. The core substrate has insulative base (20z) having first surface (F) and second surface (S) opposite the first surface, first conductive layer (34F) formed on first surface (F) of the insulative substrate and second conductive layer (34S) formed on the second surface of the insulative substrate. The core substrate is further provided with through-hole conductor 36 made by filling plating film in penetrating hole 28 for a through-hole conductor formed in insulative base (20z). Through-hole conductor 36 connects first conductive layer (34F) and second conductive layer (34S). The first surface of the core substrate corresponds to the first surface of the insulative base, and the second surface of the core substrate corresponds to the second surface of the insulative base.

Interlayer resin insulation layer (uppermost interlayer resin insulation layer) (50F) is formed on first surface (F) of core substrate 30. Conductive layer (uppermost conductive layer) (58F) is formed on interlayer resin insulation layer (50F). Conductive layer (58F) is connected to first conductive layer (34F) or a through-hole conductor by via conductor (uppermost via conductor) (60F) which penetrates through interlayer resin insulation layer (50F). Upper buildup layer (55F) is made up of interlayer resin insulation layer (50F), conductive layer (58F) and via conductors (60F). The upper buildup layer in the first embodiment is single layered. The uppermost conductive layer has pads (710FI, 710FP). Top surfaces of conductive circuits included in the uppermost conductive layer and top surfaces of uppermost via conductors make pads (710FI, 710FP).

Interlayer resin insulation layer (lowermost interlayer resin insulation layer) (50S) is formed on second surface (S) of core substrate 30. Conductive layer (lowermost conductive layer) (58S) is formed on interlayer resin insulation layer (50S). Conductive layer (58S) is connected to second conductive layer (34S) or a through-hole conductor by via conductor (lowermost via conductor) (60S) which penetrates through interlayer resin insulation layer (50S). Lower buildup layer (55S) is made up of interlayer resin insulation layer (50S), conductive layer (58S) and via conductors (60S). The lower buildup layer in the first embodiment is single layered. The lowermost conductive layer has BGA pads (71SP) for connection with a motherboard. Top surfaces of conductive circuits included in the lowermost conductive layer and top surfaces of lowermost via conductors make pads (71SP).

Upper solder-resist layer (70F) is formed on the upper buildup layer, and lower solder-resist layer (70S) is formed on the lower buildup layer. Solder-resist layer (70F) has opening (first opening) (71FI) to expose pad (710FI) and opening (second opening) (71FP) to expose pad (710FP). Solder-resist layer (70S) has opening (71S) to expose BGA pad (71SP). On BGA pad (71SP), solder bump (76S) is formed for connection with a motherboard. It is an option not to form a solder bump, and instead of a solder bump to form connection material such as Sn film. Solder bump 94 of IC chip 90 is connected to pad (710FI).

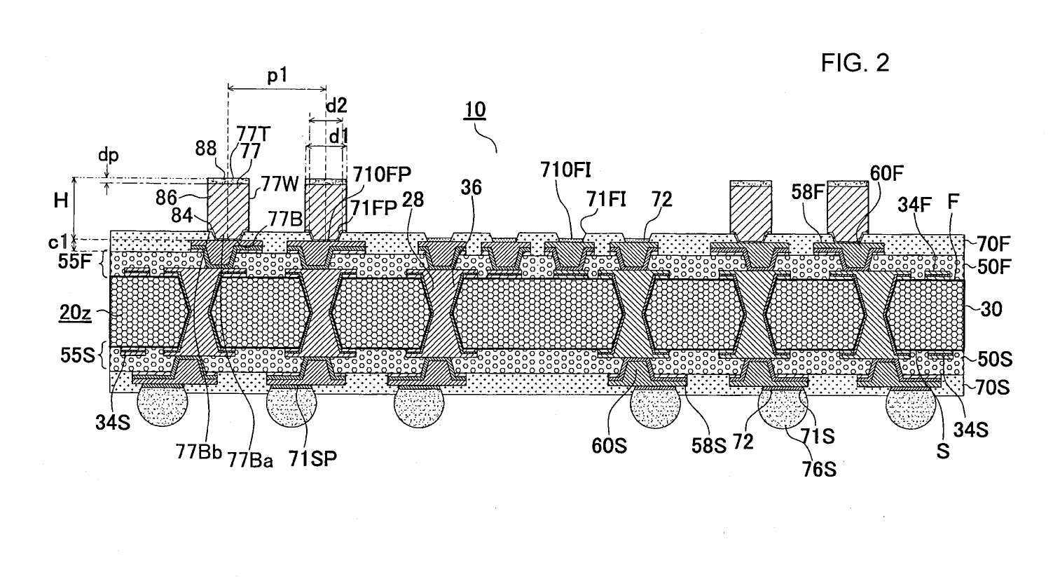

FIG. 2 is a cross-sectional view of printed wiring board 10 of the present embodiment having solder bumps (76S). Its mounting surface is provided with upper solder-resist layer (70F) and pads (710FI, 710FP). Metal post 77 is formed on pad (710FP).

Metal post 77 has top portion (77T) and its opposing bottom portion (77B). Solder-plated film 88 is formed on top portion (77T). Metal post 77 has sidewall (77W) between its top and bottom portions. Sidewall (77W) is made of electrolytic plated film 86. Bottom portion (77B) has beheaded circular cone (77Ba) corresponding to the shape of opening (71FP) in solder-resist layer (70F), and ring portion (77Bb) shaped as a ring abutting the surface of solder-resist layer (70F). Seed layer 84 is formed on the surface of bottom portion (77B). The tip end of beheaded circular cone (77Ba) of a metal post faces pad (710FP).

FIG. 2 shows a cross-sectional view of printed wiring board 10 taken at (X2-X2) in FIG. 3(B). The shape of metal posts shown in FIGS. 2 and 3(B) is a circular column. Diameter (d2) of pad (710FP) is 45 μm˜140 μm. The diameter of a pad is that of the conductor (conductive circuit or via conductor) exposed from the solder-resist layer. Diameter (d1) of metal post 77 (diameter at the top portion of the metal post) is set greater than diameter (d2). Diameter (d1) is 50 μm˜150 μm. Regarding diameter (d2) of a pad and diameter (d1) of a metal post, the ratio (d2/d1) is preferred to be 0.5˜0.9. Set at such a ratio, the pitch of the pads is reduced. Even if pitch (p1) is 0.3 mm or less, connection reliability is high between printed wiring board 10 and the upper substrate. Also, insulation reliability is high between metal posts. Distance (pitch) (p1) between adjacent pads (710FP) is 100 μm˜300 μm. Pitch (p1) less than 100 μm tends to decrease insulation reliability between metal posts. Such a pitch makes metal posts thinner, resulting in lowered connection reliability between the upper substrate and printed wiring board 10. Pitch (p1) that exceeds 300 μm increases the size of printed wiring board 10. Accordingly, stress exerted on the metal posts increases and connection reliability decreases between the upper substrate and printed wiring board 10.

When pitch (p1) is 0.3 mm or less, height (H) (distance from the top to the bottom end) of metal post 77 including the thickness of solder plated film (dp: 20 μm) is 75 μm˜200 μm, and diameter (d1) of metal post 77 is 75 μm˜150 μm. Connection reliability is enhanced between the printed wiring board of the embodiment and the upper substrate, and insulation reliability is improved between metal posts.

When pitch (p1) is 0.25 mm or less, height (H) of metal post 77 is 100 μm˜200 μm, and diameter (d1) of metal post 77 is 50 μm˜150 μm. Connection reliability is enhanced between the printed wiring board of the embodiment and the upper substrate, and insulation reliability is improved between metal posts.

The aspect ratio (height H/diameter d1) of a metal post is preferred to be greater than 1. A metal post with such a ratio mitigates stress between the printed wiring board of the present embodiment and the upper substrate, resulting in enhanced connection reliability. The aspect ratio (H/d1) is preferred to be 0.6˜3. Stress is mitigated between printed wiring board 10 and the upper substrate. In addition, the metal post will not deteriorate from fatigue, and connection reliability is enhanced between the upper substrate and printed wiring board 10.

Regarding distance (H) from the top surface of pad (710FP) to the top portion of a metal post and thickness (c1) of pad (710FP), the ratio (H/c1) is preferred to be at least 5 but 30 or smaller. When pitch (p1) is 0.3 mm or less, the value of (H/c1) is preferred to be at least 7 but 25 or smaller. Since pad (710FP) is the base of a metal post, if the value of (H/c1) is too great, the metal post may break off from the pad or the reliability of the metal post may decrease. On the other hand, if the value of (H/c1) is too small, it is hard for the metal post to mitigate stress, and connection reliability decreases.

In the first embodiment, pitch (p1) can be reduced. Since there is enough space between adjacent metal posts, insulation reliability between metal posts is high even when pitch (p1) is 0.3 mm or less. Pitch (p1) at 0.25 mm or less makes metal posts thinner. To enhance connection reliability, the aspect ratio (H/d1) of a metal post is preferred to be 0.6 or greater. When the number of pads (710FP) increases, the size of the printed wiring board increases. However, if the aspect ratio (H/d1) of a metal post is 2 or greater, such a metal post can mitigate stress caused by differences in physical properties between the upper substrate and the printed wiring board. When the value of (H/d1) exceeds 3.5, the metal post deteriorates because of heat cycles. Examples of physical properties are a thermal expansion coefficient, Young's modulus and the like.

As shown in FIG. 1, printed wiring board 10 and upper substrate 110 are connected by highly rigid metal posts 77. Thermal stress between the upper substrate and the printed wiring board is mitigated by metal posts 77. Metal posts 77 maintain the strength of an electronic device that includes the upper substrate and the printed wiring board. The electronic device is suppressed from warping caused by physical property differences between the upper substrate and the printed wiring board.

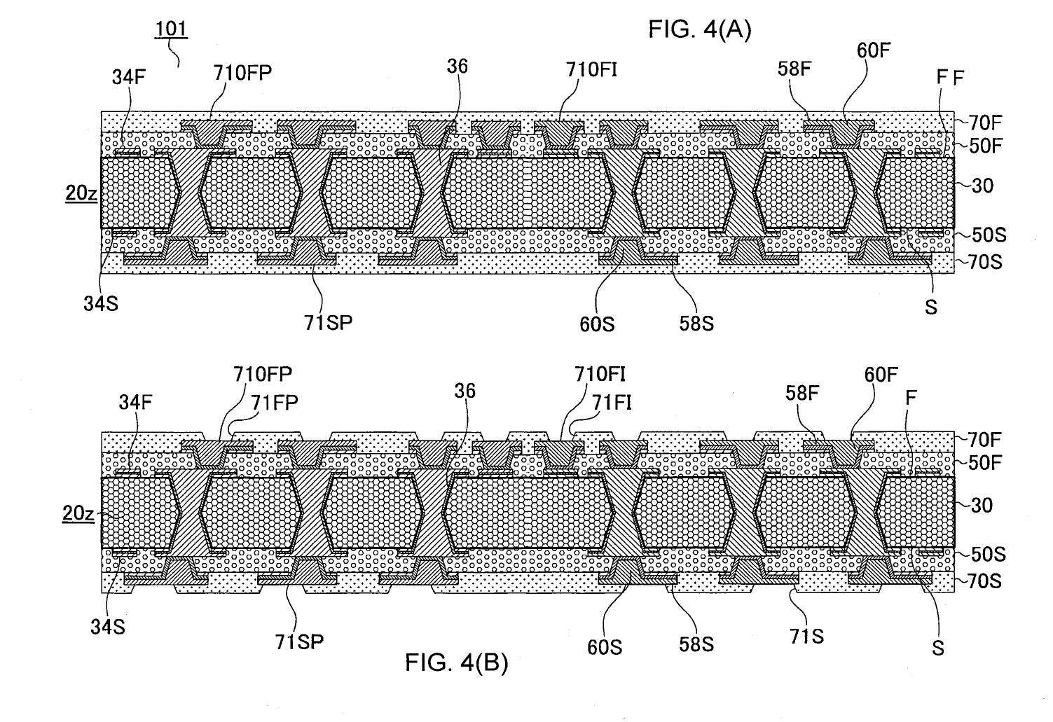

FIG. 4˜9 show a method for manufacturing a metal post. Printed wiring board 10 shown in FIG. 4(A) is manufactured by the aforementioned method described in JP2007-227512A, for example. Under its upper solder-resist layer (70F), printed wiring board 10 has pad (first pad) (710FI) for mounting electronic component 90 such as an IC chip and pad (second pad) (710FP) for mounting another printed wiring board (upper substrate) 110. Also, under solder-resist layer (70S), pad (71SP) is provided so that the printed wiring board is mounted on a motherboard.

Using a laser, first opening (71FI) is formed in upper solder-resist layer (70F), first pad (710FI) is exposed, second opening (71FP) is formed, and second pad (710FP) is exposed. In the same manner, opening (71SP) is formed in lower solder-resist layer (70S) and pad (710SP) is exposed (FIG. 4(B)).

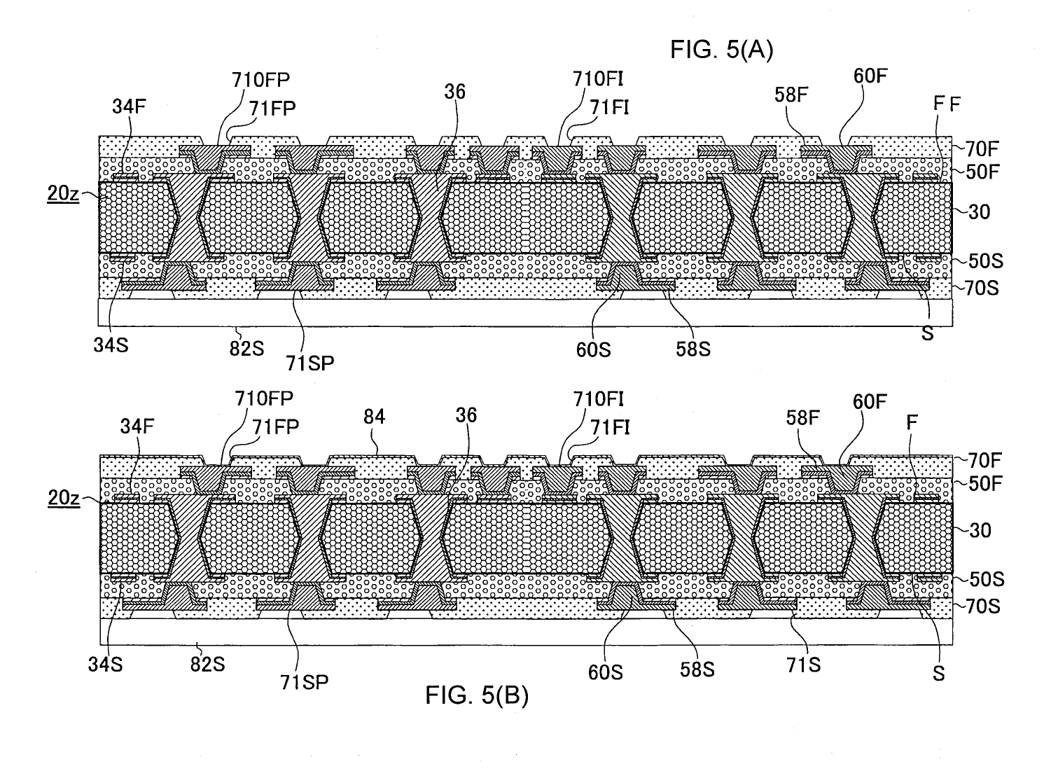

Resist (82S) is formed on the surface of lower solder-resist layer (70S) (FIG. 5(A)). Ti/Cu seed layer 84 is formed by sputtering on the surface of upper solder-resist layer (70F) and in first opening (71FI) and second opening (71FP) (FIG. 5(B)). Here, a Ti/Cu seed layer is formed by sputtering, but electroless copper plating may also be performed to form a seed layer.

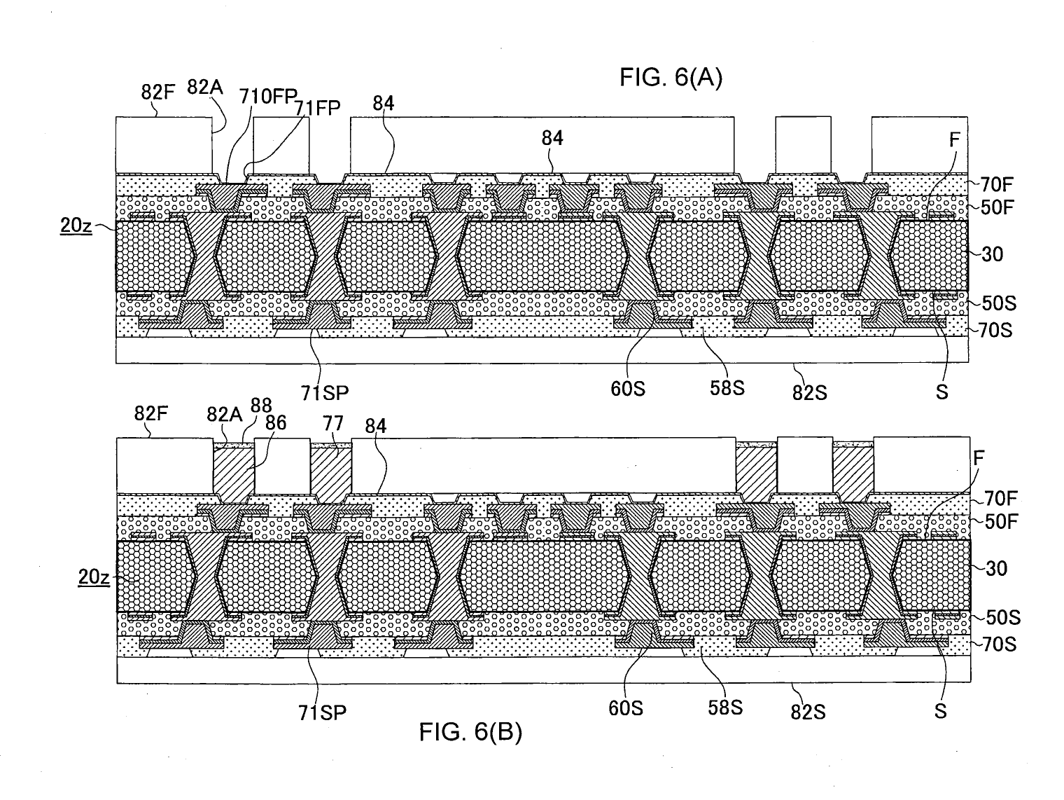

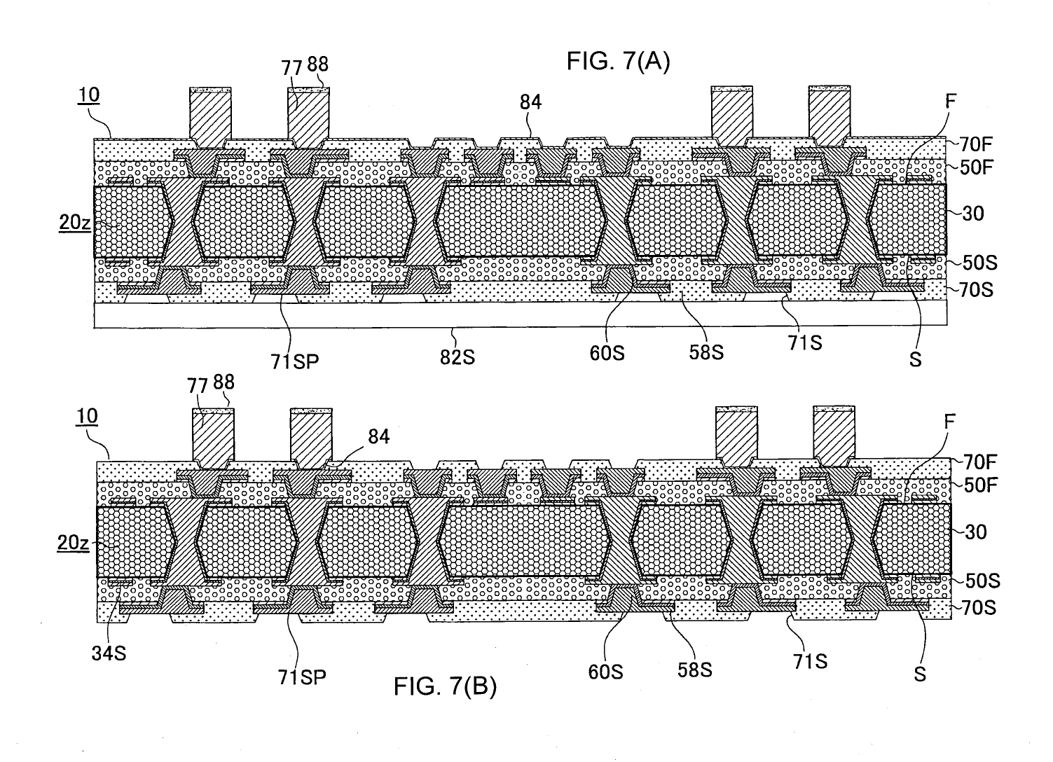

On solder-resist layer (70F) of printed wiring board 10, plating resist (82F) is formed to have resist opening (82A) which exposes second opening (71FP) and has a diameter greater than the second opening (FIG. 6(A)). Electric current flows through seed layer 84, and electrolytic copper plating 86 is filled in resist opening (82A). Moreover, solder-plated film 88 is formed by solder plating on electrolytic copper plating 86 (FIG. 6(B)). Sn/Ag soldering or Sn/Ag/Cu soldering may be employed. Alternatively, an Sn layer may be formed instead of a solder layer. Upper plating resist (82F) is removed to expose metal post 77 (FIG. 7(A)).

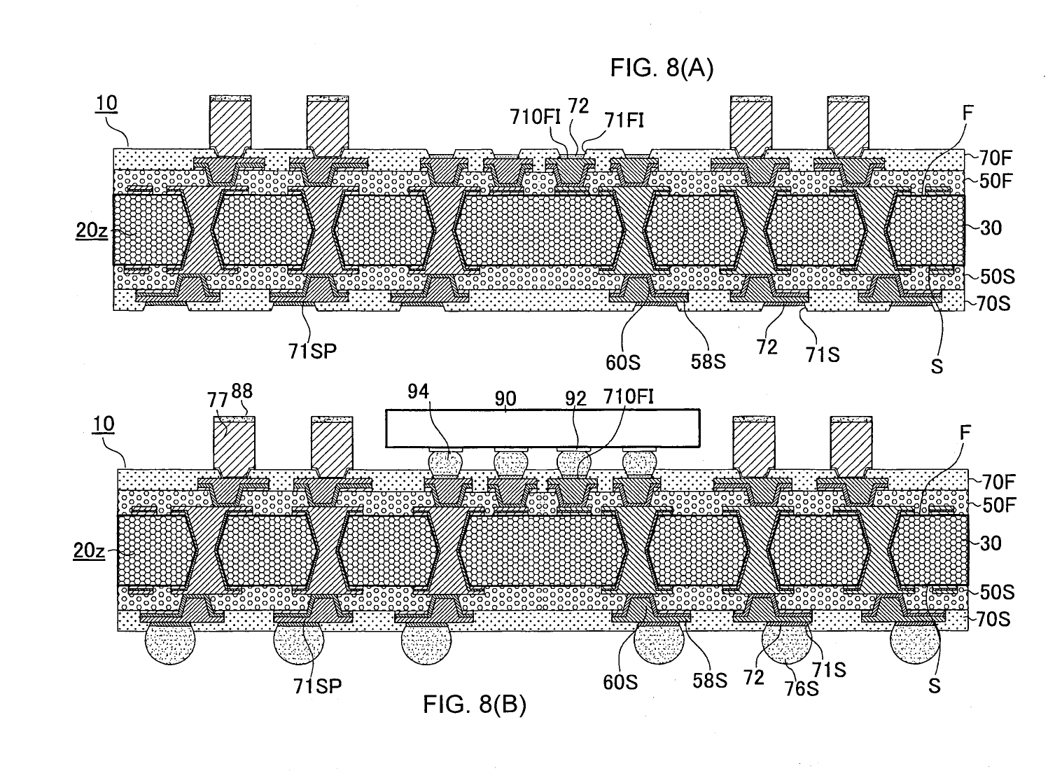

Seed layer 84, which is formed on solder-resist layer (70F) and is left exposed by metal post 77, is removed, and lower resist (82S) is also removed (FIG. 7(B)). Antioxidant surface-treatment film 72 is coated on first pad (710FI) exposed through first opening (71FI) of upper solder-resist layer (70F) and on pad (71SP) exposed through opening (71 S) of lower solder-resist layer (70S). Accordingly, printed wiring board 10 is completed (FIG. 8(A)). Antioxidant surface-treatment film 72 is a protective film to prevent oxidation of pads. Other than an OSP, examples of protective film are Ni/Au, Ni/Pd/Au, Sn and the like.

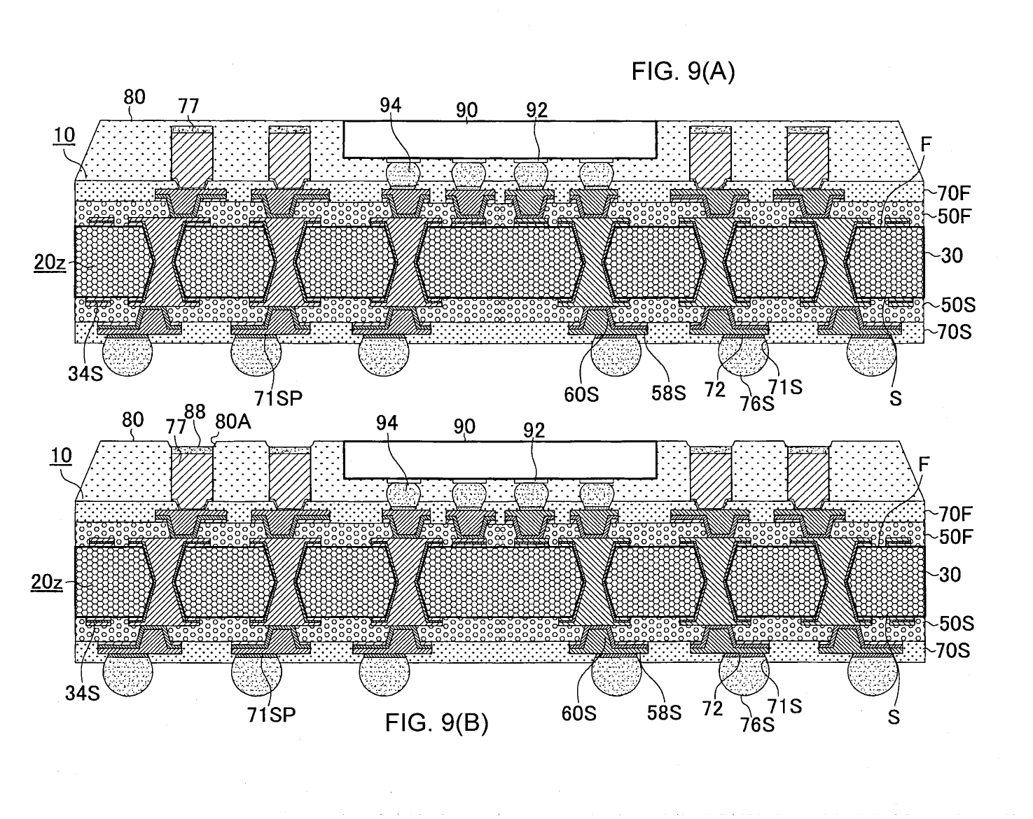

On first pad (710FI) exposed from solder-resist layer (70F) of printed wiring board 10, IC chip 90 is mounted by means of solder bump 94 formed on pad 92 (FIG. 8(B)). Mold resin 80 is filled on the printed wiring board to a level corresponding to the upper surface of IC chip 90 (FIG. 9(A)). Using a laser, opening (80A) is formed in mold resin 80 to expose solder-plated film 88 on the top portion of metal post 77 (FIG. 9(B)).

Other printed wiring board (upper substrate) 110 is bonded to metal post 77 by means of solder bump 112 so as to be mounted on printed wiring board 10 (FIG. 1).

In the method for manufacturing a printed wiring board according to the first embodiment, solder-resist layer (70F) is formed to have first opening (71FI) for connection with an IC chip and a second opening (71FP) for forming a metal post that is subsequently connected to the upper substrate. Metal post 77 is formed first in the second opening, and a solder bump is not formed in the first opening. Since metal post 77 is not affected by a solder bump, reliability is improved during the formation of the metal post, thus enhancing connection reliability between the upper substrate and the metal post.

### Second Embodiment

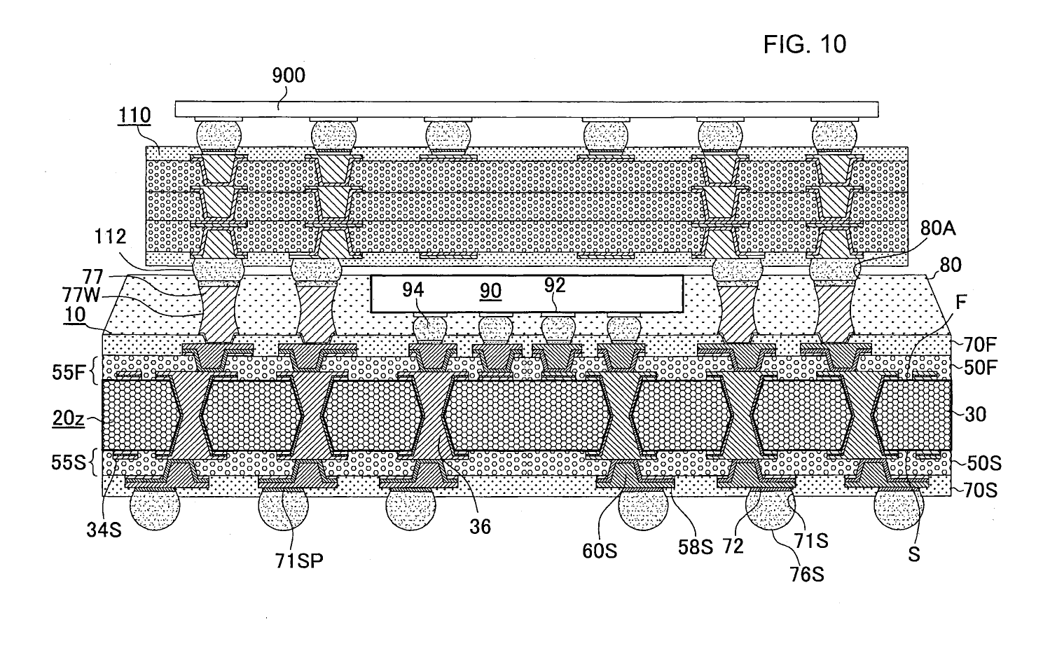

FIG. 10 shows an applied example of printed wiring board 10 according to a second embodiment of the present invention.

In the second embodiment, sidewall (77W) of metal post 77 is curved, making the diameter smaller in a portion between the top surface and the bottom surface. Since the metal post has a narrowed portion, the metal post tends to be deformed, and stress is likely to be mitigated. Even when pitch (p1) of pads (710FP) is 0.3 mm or less, connection reliability does not decrease between the printed wiring board of the embodiment and the upper substrate.

In a printed wiring board according to the second embodiment, sidewall (77W) of metal post 77 is curved, forming a narrowed portion between its top and bottom portions. Accordingly, the rigidity of the metal post is reduced and stress is mitigated by the metal post, resulting in enhanced connection reliability between the upper substrate and the metal post. In addition, since the area of sidewall (77W) of metal post 77 increases, the area also increases where the metal post makes contact with mold resin 80 that encapsulates metal post 77, and the reliability of the metal post is enhanced.

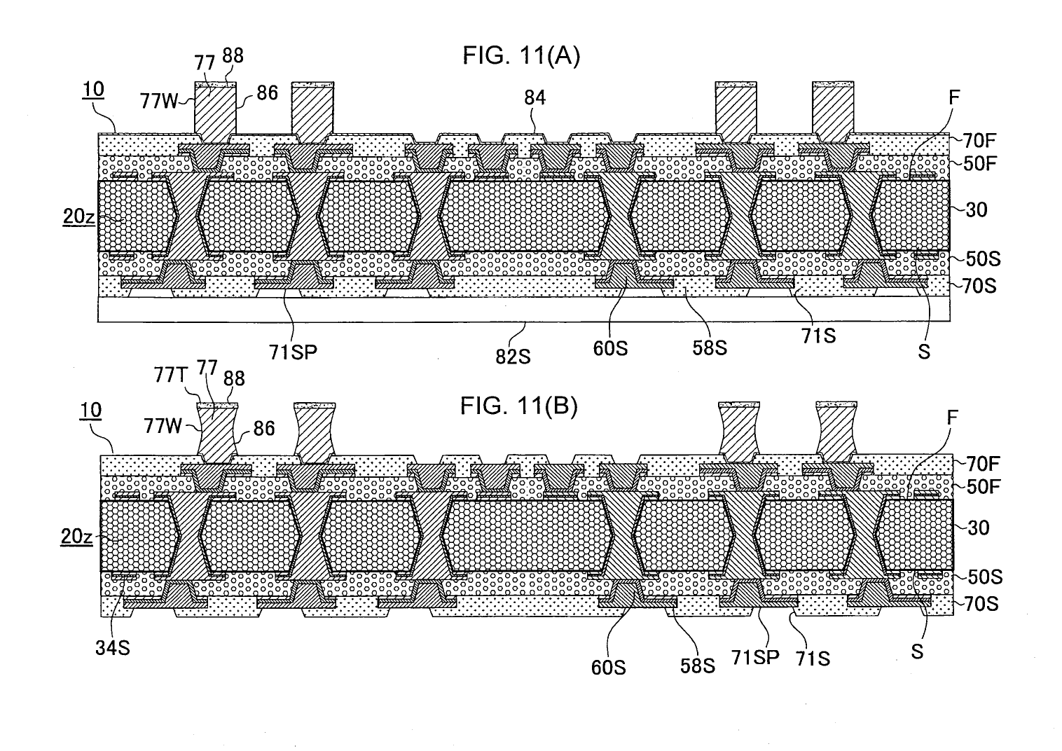

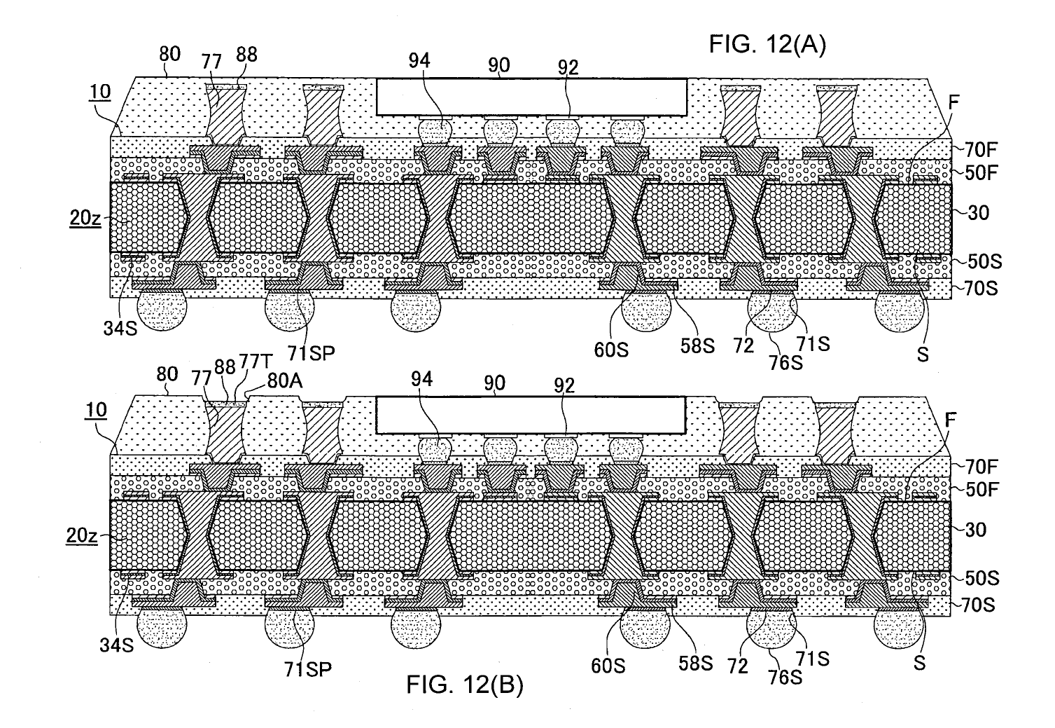

FIGS. 11 and 12 show a method for manufacturing a metal post of the printed wiring board according to the second embodiment. The same as in the first embodiment described above with reference to FIG. 4˜7, metal post 77 made of electrolytic copper plating 86 and solder-plated film 88 is formed (FIG. 11(A)). Etching is conducted to remove seed layer 84 and to form a curved portion on sidewall (77W) of metal post 77 made of electrolytic copper-plated film 86. Accordingly, metal post 77 is tapered to have an hourglass shape. During that time, top portion (77T) of metal post 77 will not be etched since it is coated by solder-plated film 88. Then, lower resist (82S) is removed (FIG. 11(B)). In the second embodiment, electrolytic copper-plated film 86 is curved when seed layer 84 is removed. However, it is an option to remove seed layer 84 first, and then to selectively etch sidewall (77W) of metal post 77 made of electrolytic copper-plated film 86 so that the sidewall is curved.

The same as in the first embodiment described above with reference to FIG. 8(B), IC chip 90 is mounted on first pad (710FI) of printed wiring board 10 by means of solder bump 92. Mold resin 80 is filled on the printed wiring board to a level corresponding to the top surface of IC chip 90 (FIG. 12(A)). Using a laser, opening (80A) is formed in mold resin 80 to expose top portion (77T) of metal post 77 (FIG. 12(B)). The same as in the first embodiment, upper substrate 110 is mounted on printed wiring board 10 (FIG. 10).

When a printed wiring board is provided with bumps for mounting an IC chip and metal posts for mounting an upper substrate, the distance between the upper substrate and the printed wiring board is greater than the distance between the IC chip and the printed wiring board. Thus, connection reliability is thought to decrease when the upper substrate is connected to the printed wiring board by tall metal posts.

A printed wiring board according to an embodiment of the present invention and a method for manufacturing such a printed wiring board according to an embodiment of the present invention are capable of enhancing connection reliability between the printed wiring board and an upper substrate mounted on the printed wiring board.

A method for manufacturing a printed wiring board according to an embodiment of the present invention is characterized by the following: on an outermost interlayer resin insulation layer and on conductive circuits, forming a solder-resist layer having a first opening to expose a conductive circuit in a central portion of the printed wiring board as well as a second opening to expose a conductive circuit in a peripheral portion of the printed wiring board; forming a seed layer on the solder-resist layer, in the first and second openings, and on the conductive circuits exposed through the first and second openings; on the seed layer, forming a plating resist to have a resist opening which exposes a second opening and has a diameter greater than the second opening; forming a metal post by filling the resist opening with electrolytic plating by means of the seed layer; removing the plating resist; removing the seed layer left exposed on the solder-resist layer; and forming an antioxidant surface-treatment film on the conductive circuit exposed through the first opening.

A printed wiring board according to an embodiment of the present invention has an uppermost interlayer resin insulation layer, a pad formed on the uppermost interlayer resin insulation layer, and a metal post formed on the pad. The sidewall of the metal post is curved, having a narrowed portion between the top and bottom.

In a method for manufacturing a printed wiring board according to an embodiment of the present invention, a solder-resist layer is formed to have a first opening for connection with an IC chip and a second opening for forming a metal post to be connected with an upper substrate. A metal post is formed first in the second opening, and a solder bump is not formed in the first opening Thus, the metal post is not affected by the solder bump. Accordingly, reliability is improved during a process of forming the metal post, and connection reliability between the upper substrate and the metal post is thereby enhanced.

In a printed wiring board according to an embodiment of the present invention, the sidewall of a metal post is curved, having a narrowed portion between the top and bottom portions. Therefore, the rigidity of the metal post is lowered, and stress is mitigated by the metal post. Accordingly, connection reliability is enhanced between the upper substrate and the metal post. In addition, since the area of the side surfaces of the metal post increases, the contact area of the metal post and mold resin also increases when the metal post is encapsulated by the mold resin, and the reliability of the metal post is thereby enhanced.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a printed wiring board, comprising:
forming a resin insulation layer on an interlayer resin insulation layer and a plurality of conductive circuits such that the resin insulation layer has a plurality of first opening portions exposing a plurality of pad portions in a central portion of the interlayer resin insulation layer and a plurality of second opening portions exposing a plurality of pad portions in a peripheral portion of the interlayer resin insulation layer;
forming a seed layer on the resin insulation layer such that the seed layer is formed on the resin insulation layer, in the first and second opening portions and on the pad portions exposed through the first and second opening portions;
forming on the seed layer a plating resist such that the plating resist has a plurality of resist opening portions exposing the plurality of second opening portions and having diameters which are greater than the second opening portions, respectively;
filling the resist opening portions with electrolytic plating material via the seed layer such that a plurality of metal posts is formed in the resist opening portions, respectively;
removing the plating resist from the resin insulation layer; and
removing the seed layer exposed on the resin insulation layer by the removing of the plating resist.

2. A method for manufacturing a printed wiring board according to claim 1, further comprising:
forming a plurality of antioxidant surface-treatment films on the pad portions exposed through the first opening portions, respectively.

3. A method for manufacturing a printed wiring board according to claim 1, further comprising:
applying surface-treatment on end portions of the metal posts prior to the removing of the plating resist.

4. A method for manufacturing a printed wiring board according to claim 3, wherein the surface-treatment comprises forming a plurality of solder plating films on the end portions of the metal posts, respectively.

5. A method for manufacturing a printed wiring board according to claim 4, wherein the surface-treatment comprises forming a plurality of solder plating films on the end portions of the metal posts, respectively.

6. A method for manufacturing a printed wiring board according to claim 4, wherein the removing of the seed layer includes etching the seed layer from the resin insulation layer such that side-wall portions of the metal posts are etched and form curved side-surfaces forming narrowed portions between the end portions and opposite end portions of the metal posts, respectively.

7. A method for manufacturing a printed wiring board according to claim 2, further comprising:
applying surface-treatment on end portions of the metal posts prior to the removing of the plating resist,
wherein the interlayer resin insulation layer is an outermost interlayer resin insulation layer, and the resin insulation layer is a solder-resist layer.

8. A method for manufacturing a printed wiring board according to claim 7, wherein the surface-treatment comprises forming a plurality of solder plating films on the end portions of the metal posts, respectively.

9. A method for manufacturing a printed wiring board according to claim 8, wherein the surface-treatment comprises forming a plurality of solder plating films on the end portions of the metal posts, respectively.

10. A method for manufacturing a printed wiring board according to claim 8, wherein the removing of the seed layer includes etching the seed layer from the resin insulation layer such that side-wall portions of the metal posts are etched and form curved side-surfaces forming narrowed portions between the end portions and opposite end portions of the metal posts, respectively.

11. A printed wiring board, comprising:
an interlayer resin insulation layer;
a plurality of pad portions formed on the interlayer resin insulation layer;
a resin insulation layer formed on the interlayer resin insulation layer and the pad portions such that the resin insulation layer has a plurality of first opening portions exposing the pad portions in a central portion of the interlayer resin insulation layer and a plurality of second opening portions exposing the pad portions in a peripheral portion of the interlayer resin insulation layer; and
a plurality of metal posts formed on the pad portions in the peripheral portion of the interlayer resin insulation layer, respectively, and having curved side-wall portions forming narrowed portions between the end portions and opposite end portions of the metal posts, respectively.

12. A printed wiring board according to claim 11, further comprising:
a plurality of antioxidant surface-treatment films formed on the pad portions exposed through the first opening portions, respectively.

13. A printed wiring board according to claim 11, further comprising:
a plurality of solder plating films formed on the end portions of the metal posts, respectively.

14. A printed wiring board according to claim 11, wherein the plurality of metal posts is formed on the pad portions in the peripheral portion of the interlayer resin insulation layer, respectively, at a pitch in a range of 0.3 mm or smaller, the interlayer resin insulation layer is an outermost interlayer resin insulation layer, and the resin insulation layer is a solder-resist layer.

15. A printed wiring board according to claim 14, wherein each of the metal posts has a diameter in a range of 50 to 150 μm and an aspect ratio in a range of 0.6 to 3.

16. A package-on-package device, comprising:
a first substrate;
an IC chip mounted on the first substrate;
a second substrate mounted on the first substrate; and
a mold resin layer filling a space formed between the first substrate and the IC chip,
wherein the first substrate includes an interlayer resin insulation layer, a plurality of pad portions formed on the interlayer resin insulation layer, a resin insulation layer formed on the interlayer resin insulation layer and the pad portions such that the resin insulation layer has a plurality of first opening portions exposing the pad portions in a central portion of the interlayer resin insulation layer and a plurality of second opening portions exposing the pad portions in a peripheral portion of the interlayer resin insulation layer, and a plurality of metal posts formed on the pad portions in the peripheral portion of the interlayer resin insulation layer, respectively, and having curved side-wall portions forming narrowed portions between the end portions and opposite end portions of the metal posts, respectively, the mold resin layer has a plurality of opening portions exposing the end portions of the metal posts, respectively, the first substrate has a plurality of first bumps mounting the IC chip on the pad portions in the central portion of the interlayer resin insulation layer, and the second substrate has a plurality of second bumps connecting to the end portions of the metal posts exposed from the opening portions of the mold resin layer.

17. A package-on-package device according to claim 16, wherein the first substrate includes a plurality of antioxidant surface-treatment films formed on the pad portions exposed through the first opening portions, respectively.

18. A package-on-package device according to claim 16, wherein the first substrate includes a plurality of solder plating films formed on the end portions of the metal posts, respectively.

19. A package-on-package device according to claim 16, wherein the plurality of metal posts is formed on the pad portions in the peripheral portion of the interlayer resin insulation layer, respectively, at a pitch in a range of 0.3 mm or smaller, the interlayer resin insulation layer is an outermost interlayer resin insulation layer, and the resin insulation layer is a solder-resist layer.

20. A package-on-package device according to claim 19, wherein each of the metal posts has a diameter in a range of 50 to 150 μm and an aspect ratio in a range of 0.6 to 3.
